(19) United States
(12) Patent Application Publication
(10) Pub. No.: US 2025/0057168 A1
(43) Pub. Date: Feb. 20, 2025

(54) ARTICLE WITH AN ANTIBACTERIAL FINISH AND METHOD FOR PRODUCTION OF SAME

(71) Applicant: Atomos Master Key GmbH, Freienbach (CH)

(72) Inventor: Fabio Huther, Ermatingen (CH)

(73) Assignee: Atomos Master Key GmbH, Freienbach (CH)

(21) Appl. No.: 18/722,037

(22) PCT Filed: Nov. 30, 2022
(86) PCT No.: PCT/EP2022/083912

§ 371 Date: Jun. 20, 2024

(30) Foreign Application Priority Data
Dec. 21, 2021 (EP) 21216404.0

(51) Int. Cl. A01N 59/16; A01N 59/00; A01N 59/20; A01P 1/00; B01D 29/15; B01D 29/58; B01D 39/16; C23C 14/20; D06M 10/06; D06M 16/00; D06M 23/16

(52) U.S. Cl. CPC A01N 59/16; A01N 59/00; A01N 59/20; A01P 1/00; B01D 29/15; B01D 29/58; B01D 39/1607; C23C 14/205; D06M 10/06; D06M 16/00; D06M 23/16; B01D 2239/0442; B01D 2239/0478; B01D 2239/0618

(57) ABSTRACT

Articles which include an electrically nonconductive substrate are provided with an antibacterial finish by sputter-coating the substrate with particles of titanium and at least one further metal such that the coated particles are arranged in various combinations as clusters on the substrate, the particles being electrically conductively connected together within the clusters, and the clusters being arranged on the substrate at a distance from each other in the manner of islands and electrically insulated from each other.

### CROSS-REFERENCE TO RELATED APPLICATIONS

This application is the U.S. National Phase of PCT Appln. No. PCT/EP2022/083912, filed Nov. 30, 2022, which claims priority from European Patent Application No. 21216404.0, filed Dec. 21, 2021, the entire disclosures of which are incorporated by reference herein.

### TECHNICAL FIELD

The invention relates to an article with an antibacterial finish and to a method for producing an article with an antibacterial finish.

### BACKGROUND

Pathogenic microorganisms such as bacteria or viruses pose an increasing danger to human and animal health. Transmission may occur in particular via contaminated water, aerosols, droplets or by direct contact. Suitable hygiene measures can kill microorganisms or prevent them from spreading further.

Various techniques can be used to treat drinking water, such as, for example, filtration to remove particles, reverse osmosis to remove salts, and the addition of ozone or chlorine or irradiation with UV light for disinfection or for reducing infectious microorganisms. Chemical contamination by chlorine must remain within permitted limits. Moreover, chlorinated water is not neutral in terms of odor and flavor.

It is also known to treat water electrochemically by applying a DC or AC voltage signal to electrodes in the water. Such electrolysis methods can, for example, remove unwanted ions such as heavy metal ions from the water. Similarly, desired particles from the electrode material can also be added to the water. In particular, charged and electrically neutral nanoparticles, for example silver and/or copper particles, can be added to the water by electrolysis. Liquid dispersions including such particles are also known as colloids. Silver ions have a disinfecting action. They can kill viruses, bacteria and other microorganisms. Copper ions are active against fungi and/or algae present in water.

It is also known that reactive oxygen species (ROS), or oxygen radicals for short, have a damaging action on bacteria and viruses. Free radicals are short-lived molecular fragments, such as, for example, the hydroxyl free radical OH. As a radical, it has a single, unpaired electron and is thus highly reactive. Such free radicals denature protein, break DNA/RNA chains, and destroy lipid envelopes. Some amino acids in proteins, such as, for example, aromatic rings and thiol-containing amino acids, are highly susceptible to free radicals and reactive oxygen species. Amino acids with aromatic ring groups such as phenylalanine, tyrosine, tryptophan and histidine as well as amino acids with sulfur groups such as methylamino acid, cysteine and cystine amino acids are based on a carbon with four functional groups: amino group —NH₂, carboxyl group —COOH, H and R groups with various forms.

DE10009643A1 discloses a device for treating contaminated water in which the water flows through a chamber. Four electrodes are arranged in this chamber and are connected to electrical terminals guided out of the chamber in watertight manner. At least one of the electrodes contains silver and/or copper or an alloy of these metals. A DC or AC voltage is applied to the electrodes, the polarity being alternated in such a way that, on a time average, each electrode is used as the cathode and as the anode for the same length of time. Due to the electrical voltage supplied from outside via the terminals, the electrodes release silver and/or copper ions into the water. Ionized nanoparticles in the water are comparatively reactive and readily combine with harmful molecules in the water. However, due to their reactivity, such ionized particles can also pose a danger to the environment and living organisms. The content of ionized particles should accordingly be limited when electrochemically releasing particles into water.

Killing and/or preventing the spread of microorganisms is not only of great importance in water treatment. Suitable measures for improving hygiene are also required in many other areas, in particular in hospitals, catering establishments and the food industry, where it is often not possible to install equipment to kill microorganisms, as is the case with water treatment. The need for an external power supply is also problematic for various applications.

Certain bacteria may also be undesirable because they cause effects that are unpleasant for humans. This includes, for example, the odor of sweat, which is caused by the bacterial breakdown of fatty acids present in sweat.

### SUMMARY

It is an object of the present invention to propose an article or a device which has an antibacterial effect without the input of electrical energy, and to provide a method for the production thereof. In the context of the present invention, the phrase “antibacterial effect” should be taken to mean an inhibitory or destructive effect on representatives of at least one of the following categories: microorganisms, in particular anaerobic mesophilic microorganisms, pathogenic microorganisms, bacteria, viruses, fungi and algae.

This object is achieved by an article with an antibacterial finish and by a method for the production thereof according to one or more of the features disclosed herein.

In electrically highly conductive metals such as silver and copper, the mobility of valence electrons is comparatively high. For simplicity, this is also referred to as an electron sea. This promotes the formation of free radicals.

Surprisingly, microorganisms can be rendered harmless by various alloys with differing redox potentials without external energy input. This also applies to microscopic particles of an alloy or in compounds comprising at least two components, at least one of which is a metal. In the present document, the term “alloy” also includes microscopic and nanoscale particles of such compounds.

The antibacterial effect is particularly strong if a plurality of small alloy particles with different compositions of the respective components are arranged at small distances from each other. Arrangements comprising an elevated proportion of nanoparticles are particularly effective. Nanoparticles comprise associations of a few to several thousand atoms or molecules. Compared to larger agglomerates, they have a large surface-to-volume ratio. The properties of nanoparticles can differ significantly from those of larger particles. In particular, nanoparticles generally have greater chemical reactivity. In the vicinity of nanoparticles, repulsive electrostatic interaction is significantly stronger than attractive van der Waals interaction. Electron clouds on the surface of nanoparticles form free radicals. These can destroy proteins such as bacterial cell membranes. This also applies to hydrogen bridge bonds between the S1 protein and S2 protein of viruses.

Nanoscale particles made of alloys or compounds including silver and/or copper are particularly effective in combating bacteria and/or fungi. The particles may also comprise compounds with other metals such as for example titanium, nickel or steel/iron and carbon.

Various articles can be provided with an antibacterial finish by using such nanoscale particles. At least two different metals are here deposited on a substrate by physical vapor deposition and in particular by sputtering. Sputtering is particularly suitable because important process parameters such as the average size of the particles passing from the target into the gas phase and deposition rate on a surface portion of the substrate can be well controlled. The individual metals can be deposited sequentially/temporally one after the other or in parallel/approximately simultaneously in a vacuum chamber. The material to be coated is detached from appropriate targets, for example by ion bombardment, and transferred into the gas phase. The deposition rate on the substrate can be influenced by an electric field. In addition, magnetron sputtering can achieve a significantly higher removal rate at the same process pressure thanks to a magnetic field at the target. Magnetron sputtering is also advantageous because a substrate can be coated at a distinctly lower process pressure, so enabling highly efficient and effective coating of a substrate. This is particularly the case if the substrate is a sheet structure which is coated on one or both sides in a roll-to-roll method. The sheet structure may here be unwound from a supply roll and rewound onto a take-up roll alternatively continuously or discontinuously/stepwise. Targets made from the same or different materials may be arranged in any desired combinations on one or both sides of the sheet structure and, in relation to the process direction, one after the other and/or next to each other. The targets may be arranged in the process chamber in such a way that the high-energy plasma strikes all the targets simultaneously. Alternatively, means may be provided which enable sequential coating of the substrate with material from the various targets. For instance, the orientation of the plasma source may be variable. Alternatively, each target can be individually influenced by a dedicated plasma source. The targets may also be arranged in different portions of a high-vacuum chamber such that coating can be separately controlled in the individual portions. Alternatively, the coating installation may comprise a plurality of independent high-vacuum chambers for sequentially sputtering different materials.

The result of the coating process on the substrate can be influenced by the nature and arrangement of the targets in the process chamber. This applies in particular with regard to the quantity and sequence of particles which are detached from the various targets and deposited on the substrate. For instance, a binder which adheres well to the substrate and has good binding properties for further materials to be deposited may be deposited first. A preferred binder is in particular titanium. Titanium has excellent adhesion for example to nonwoven fabrics and textile sheet structures and, due to its structure, has a plurality of docking sites for further materials, in particular for metals such as for example copper (Cu), silver (Ag), gold (Au), nickel (Ni), or iron (Fe).

Each of the metals may be deposited once or a number of times. A plurality of clusters or nanoscale particles are here formed on the substrate, which are arranged in an island-like distribution and may differ in terms of the number and type of contiguous atoms or molecules.

By specifying or setting certain process parameters, the result of coating on the substrate can be defined in accordance with the respective requirements. Such process parameters may for example relate to the configuration of the process chamber itself and/or control of the coating process.

Examples of such process parameters are the number, size and arrangement of targets in the process chamber and the materials thereof; process pressure in the process chamber; average energy or velocity of the particles emitted by the ion radiation source; distance of the target from the substrate in the process chamber; nature and strength of electrical and/or magnetic fields in the process chamber which influence deposition rate when coating the substrate; duration of coating intervals; speed of substrate portions relative to the respective target during coating; sequence of coating with material from different targets.

One or more such process parameters of the coating installation can be specified or set in accordance with the respective requirements placed on the coated substrate in order to deposit one or more metals in a defined way.

In particular, for example for coating steps carried out one after the other with various metals, the coating duration for each of the coating intervals can be individually specified. The corresponding times may be specified such that a large number of particle islands, which are arranged in electrically insulated manner at small distances from each other, are formed per unit area of the substrate. The compositions of these particle islands or the number and type of the atoms or molecules deposited and in each case joined together within a particle island are not uniform. They are individual for each particle island and can vary greatly in some cases.

Starting from an uncoated substrate, the proportion of particles deposited on the substrate increases with the duration of the coating intervals. The proportions of the various deposited materials may, for example, be controlled by individually specifying the duration of the coating intervals for each of these materials.

Particles can be deposited directly onto free areas of the substrate surface or be attached to particles that have already been deposited. The proportion of particles that combine with particles already deposited on the substrate increases with increasing coating duration. Particle islands are formed, the number and size of which increase in an initial phase with increasing deposition duration. The average distance between adjacent particle islands decreases concomitantly. Further deposition of particles may result in adjacent particle islands that are very small distances apart coalescing into a single particle island. After an initial increase, the rate of newly formed particle islands per unit time decreases in a second phase with increasing coating duration. This increases the proportion of particles that are deposited on existing particle islands, and adjacent particle islands increasingly coalesce.

Given a sufficiently long coating duration, approximately all of the particle islands would join together to form a contiguous layer on the substrate surface.

The antibacterial effect of a coated substrate is particularly effective if the average number of particle islands per unit area of substrate tends toward large or maximal. The average distance between adjacent particle islands is then comparatively small. In many applications, however, a distinctly smaller number of particle islands per unit area is enough to impart a sufficiently good antibacterial effect to the substrate. This can be achieved, for example, by correspondingly short coating intervals. Since coating a substrate in a vacuum chamber is complex and costly, substrates can in this way be provided with a relatively inexpensive yet effective antibacterial finish.

In the case of sequential coating of the substrate with material from a plurality of targets, the duration of the individual coating intervals may for example be specified such that the total coating duration amounts to between approximately 10% and approximately 90% of the total coating duration of the first phase during which the average number and size of particle islands on the substrate surface increases. The mass ratio or the ratio of the number particles of the different materials deposited on a unit area of the substrate can be controlled, for example, by corresponding ratios of the duration of the associated coating intervals.

A suitable duration of the coating intervals may, for example, be determined experimentally for each of the materials to be coated. In particular, the proportion by mass deposited per unit time on a unit area of the substrate can be determined for each material. Optimum material compositions of the coating and the corresponding process parameters, in particular the duration of the individual coating intervals, can be determined by testing the antibacterial effect or other properties on differently coated substrates. The process parameters may, for example, be defined such that the antibacterial effect of the coated substrate is maximal under specified measurement conditions. Alternatively, the process parameters may similarly be optimized such that the antibacterial effect is sufficient for a specific application. The coating intervals and duration of production are correspondingly shorter and material consumption is lower, as are manufacturing costs.

Processes in which the substrate is a strip-like sheet structure that is conveyed from roll to roll within the process chamber are particularly efficient. The width of such substrate strips is preferably greater than 1 m and is, for example, between 1.5 m and 2 m. The dimensions of the process chamber in which the substrate strips are to be coated limit the maximum possible width of the substrate strips.

The substrate is preferably cleaned prior to metal deposition. This can be performed, for example, by plasma or an ion plasma source. The latter can be arranged in the same process chamber in which coating with the metals also takes place.

Preferably, titanium is deposited on the substrate from a titanium target in a first coating step. Due to its structure, titanium has the property that it can bond well to the substrate and has a plurality of docking sites for binding further particles such as atoms or molecules. On deposition of one or more metals in one or more further coating steps, the titanium particles are preferential nucleation sites for the formation of different particle islands. On deposition of further metal particles, the latter preferentially bond to titanium particles on the substrate. Some of the further metal particles are deposited directly on the substrate surface.

The duration of the individual coating intervals is selected to be sufficiently short for no continuous electrically conductive layer to be created on the surface of the substrate. The substrate itself is generally electrically nonconductive. If required, an electrically conductive substrate can be provided with an electrically insulating layer prior to deposition of metals thereon. The average size of the particle islands is preferably less than 100 nm. It may be, for example, in the range from approximately 1 nm to approximately 100 nm and in particular between 10 nm and 50 nm. The size of a particle island is defined by its maximum extent or its greatest thickness.

The average distance of adjacent particle islands from each other may, for example, be of a similar order of magnitude or greater. It is, however, preferably less than 10000 nm.

The formation of different particle islands or clusters can be promoted by at least one of the metals in a sequence being sputtered more than once. A particularly good antibacterial effect can be achieved on a substrate by depositing the following materials on the substrate in the stated sequence: titanium-copper-silver-copper-silver.

The substrate is preferably a textile or non-textile sheet structure, for example a nonwoven or a woven fabric. In sheet structures with structured surfaces made from fibers, the usable surface area for deposition of particles is greater than in the case of smooth surfaces. In addition, the three-dimensional surface structure promotes the formation of particle islands that are not electrically connected together. The surface structure furthermore improves the adhesion of deposited particles. A further advantage is that such sheet structures have open pores or through-openings between the fibers and are usable as filters for fluid media.

The material of the substrate may, for example, comprise a plastics material, in particular a polyamide such as nylon, polypropylene (PP), polyethylene (PE), polyethylene terephthalate (PET), or polymethyl methacrylate (PMMA or acrylic polymer).

The substrate may, for example, be a hydrophobic nonwoven or woven fabric made from PET with a linear fiber or yarn density of approximately 0.15 denier. One denier corresponds to approximately 1.1×10⁻⁴ grams per meter. In a further embodiment, the substrate may, for example, be a hydrophilic nonwoven or woven fabric made from PP with a linear density of approximately 9 denier.

Composite materials including two or more polymers, for example microfilament nonwoven fabrics, as are known under the trade name Evolon® from Carl Freudenberg KG in Germany, are particularly suitable.

In further embodiments, the material of the substrate may, for example, also comprise ceramic materials.

In the case of substrates in the form of flexible sheet structures, the coating materials are preferably sputtered onto one or both surfaces of the substrate in a roll-to-roll method. This enables efficient and inexpensive coating of the substrate.

A plurality of coating materials, in particular titanium, copper, and silver, are preferably applied, for example by magnetron sputtering, to the substrate in a high-vacuum chamber. In this process, high-energy plasma or ions detach nanoparticles from targets comprising the respective coating material, which are then deposited from the gas phase onto the substrate. Corresponding nanoparticles can be detached from a plurality of different targets simultaneously or alternately one after the other. Coating with the various target materials is preferably carried out sequentially one after the other. Since titanium adheres well to most substrates, the substrate is usually coated with titanium first. The other coating materials are then preferably likewise sputtered one after the other.

The targets may, for example, be arranged in the coating chamber one after the other or next to each other in the process direction. The device for generating plasma or in general the high-energy particles may be configured, for example, to detach nanoparticles for deposition on the substrate from all the targets simultaneously. Alternatively, the device may be configured to bombard the individual targets sequentially one after the other, for example with one or more plasma sources. This has the advantage that the deposition of different nanoparticles on the substrate can be better controlled. In particular, parameters such as sequence and coating duration or quantity of individual materials to be applied to the substrate can be specified and controlled in this way.

Preferably, titanium is deposited on the substrate first. Titanium has a high degree of covalent bonding and, due to its octahedral coordination geometry, is ideally suitable as a binder. Titanium adheres well to polymer substrates and enables strong attachment of nanoparticles from the further targets, in particular copper and silver.

Depending on the intended use, the coated substrate itself be used as an article or device with an antibacterial finish. For example, nonwoven fabrics or textiles coated in the stated manner can be used in this way as cleaning cloths with an antibacterial effect or in the medical field as antiseptic pads or packaging. Instead of flexible sheet structures, surface areas of three-dimensional and/or rigid articles can also be provided with an antibacterial finish by deposition of the metals in the stated manner. Examples include door handles, handrails on banisters, control buttons on appliances, work surfaces, etc.

Substrates with an antibacterial finish may also take the form of components of devices or articles. Examples of such articles are water filters, air filters, protective masks, wound dressings, garments, insoles, etc., at least one ply of the substrate constituting a surface portion of the article or being embedded in the article.

### BRIEF DESCRIPTION OF THE DRAWINGS

The invention is described in greater detail below with reference to figures, in which:

FIG. 1 is a schematic representation of substrate coating in a sputtering installation,

FIG. 2 is a schematic representation of the surface of a sheet structure coated with various materials,

FIG. 3 shows a filter cartridge,

FIG. 4 shows a respirator mask,

FIG. 5 shows a garment.

### DETAILED DESCRIPTION

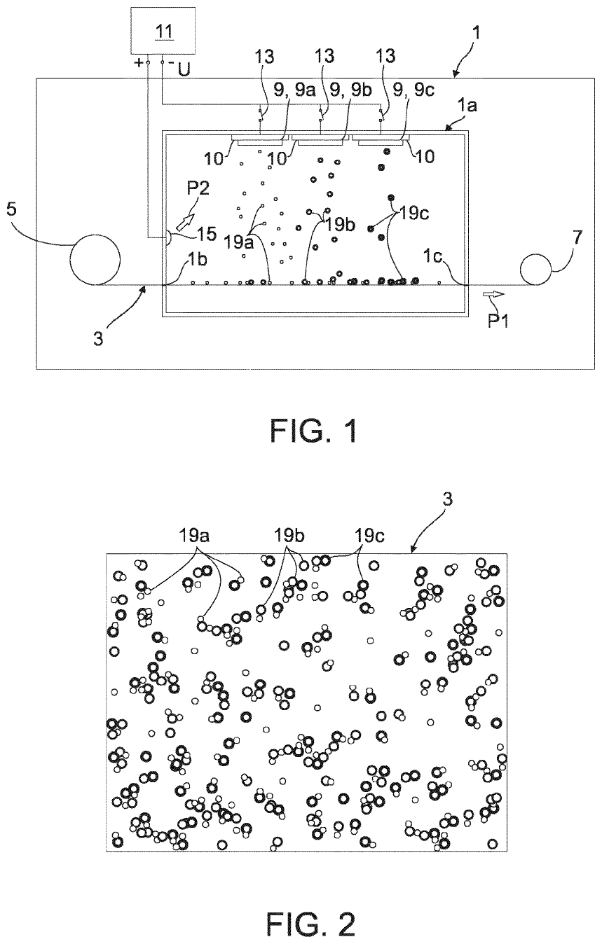

FIG. 1 is a schematic diagram of an evacuatable chamber 1 of a sputtering installation, in which a substrate to be coated in the form of a strip-like sheet structure 3 is arranged to be unwound from a supply roll 5 and rewound onto a take-up roll 7. The chamber 1 comprises a region designated as the process chamber in which the sheet structure 3 is coated. The process chamber is preferably shielded from adjacent regions of the chamber 1 by a wall 1a. On unwinding from the supply roll 5 and rewinding onto the take-up roll 7, the sheet structure 3 can be guided via two passage openings 1b, 1c in the wall 1a through the process chamber in a conveying direction represented by an arrow P1. A plurality of targets 9 made from various materials to be deposited on the sheet structure 3 are arranged within the process chamber, for example a first target 9a made of titanium (Ti), a second target 9b of copper (Cu) and third target of silver (Ag). For example, as shown in FIG. 1, the targets 9 can each be arranged on an electrically conductive carrier 10 opposite a plane defined by the passage openings 1b, 1c on a portion of the wall 1a of the process chamber. Such apparatuses can be used to coat sheet structures 3 on one side. Alternatively, targets 9 may also be arranged on the wall 1a of the process chamber on both sides of a sheet structure 3 to be coated (not shown). The sputtering installation comprises a controller 11 with a voltage source which supplies a DC voltage or in general a voltage function, for example a pulsed voltage with a specified polarity. Each target 9a, 9b, 9c is preferably connectable as a cathode via an individual switching element 13 to the negative pole of this voltage source. The positive pole of the voltage source is connected to one or more anodes 15 that are used to accelerate ions from a plasma source (not shown) toward one or more of the targets 9. This is shown symbolically in FIG. 1 by the arrow P2. The plasma is preferably generated from argon gas introduced into the process chamber. The targets 9a, 9b, 9c can be connected individually or in any desired combinations via the switching elements 13 to the negative terminal of the voltage source 11. The electric field between the anode 15 and the connected cathode(s) accelerates the positively charged argon ions toward the respective target 9a, 9b, 9c where, on impact, they eject atoms or particles comprising more than one atom from the respective target material. These atoms or particles receive momentum toward the opposite portion of the sheet structure 3, where they adhere as a deposit.

FIG. 2 is a schematic diagram of a magnified portion of the surface of the substrate or sheet structure 3 during or after coating with particles 19a, 19b, 19c from the various targets 9a, 9b, 9c in FIG. 1. The particles 19a, 19b, 19c are arranged in a plurality of different combinations as clusters or islands on the substrate surface. Titanium particles 19a are usually sputtered first. They act as nucleation sites for particle islands. In one or more subsequent process steps, silver and/or copper are, for example, sputtered as further particles 19b, 19c. These preferentially bond to other particles already deposited on the substrate, in particular to titanium particles 19a.

In sheet structures 3 that are coated with titanium (Ti), silver (Ag) and copper (Cu), the material proportion ratios are preferably in the following ranges:
(Ti:Cu)=(1:4) to (1:12), for example approximately (1:8),
(Cu:Ag)=(1:2) to (1:6), for example approximately (1:4).
   These figures relate to the number of particles or atoms of the various materials deposited on the sheet structure 3. Unless otherwise stated, tolerances of ±15% apply in each case.

Taking account of the atomic masses of titanium (approx. 47.8 u), copper (approx. 63.5 u) and silver (approx. 107.8 u), the material proportion ratios could also be stated by the respective proportions by mass. The latter can be determined comparatively easily and accurately, for example, by measuring the weight before and after sputtering.

The mass of silver particles deposited per m² of surface of the sheet structure 3 is preferably of the order of magnitude of approximately 50 mg to approximately 100 mg and amounts for example to approximately 75 mg. The sheet structure 3 can be coated one side or, alternatively, on both sides.

Substrates can be provided with a particularly effective antibacterial finish by sequential sputtering of a sequence of titanium-copper-silver-copper-silver.

In further embodiments, the sheet structure 3 can be coated, for example, with titanium, silver, copper, and gold (Au). The material proportions are preferably in the following ranges:
(Ti:Cu)=(1:1) to (1:4), for example approximately (1:2),
(Cu:Ag)=(1:2) to (1:4), for example approximately (1:3),
(Cu:Au)=(2:1) to (8:1), for example approximately (5:1).

In further alternative embodiments, titanium as binder and at least one further metal from the group silver (Ag), copper (Cu), gold (Au), nickel (Ni), and iron (Fe) can be deposited in a similar manner onto a sheet structure 3 or in general onto a substrate. The proportions of the individual materials generally differ. Preferably, at least two further metals are sputtered in addition to titanium.

The substrate is preferably a textile or non-textile sheet structure 3, in particular a nonwoven or woven fabric which is produced for example from a polymer and has a porous fiber structure. Such sheet structures 3 may be provided in different material thicknesses and with different pore sizes and are suitable as filter elements for fluids such as water and air. In comparison with conventional filter elements, filter elements according to the invention that comprise a sheet structure 3 coated with at least two different metals also have a microbicidal effect. The are also suitable for binding heavy metals.

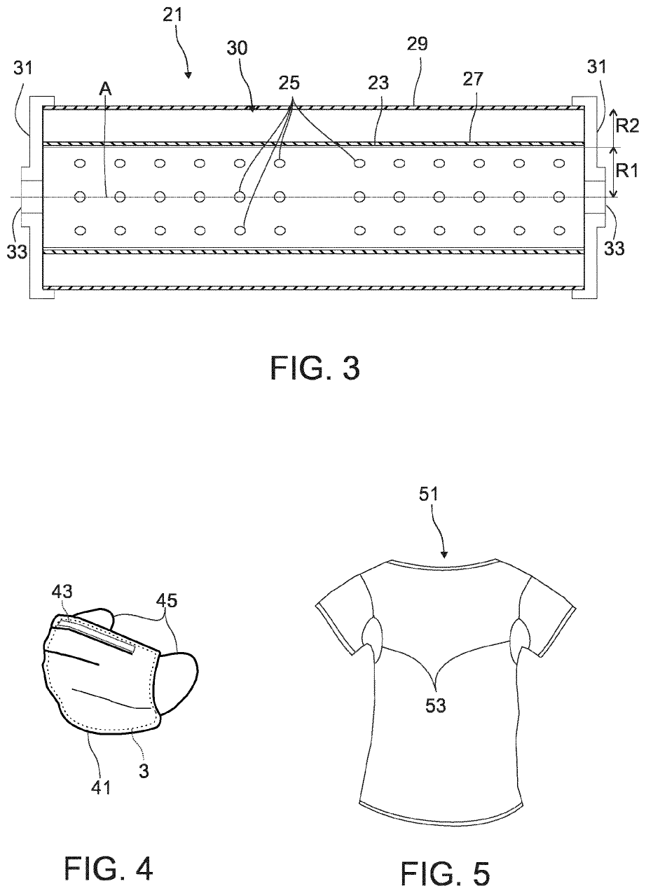

FIG. 3 shows a longitudinal section through a filter cartridge 21 with an antibacterial finish. The cartridge comprises a cylindrical inner wall 23 that is arranged at a distance or radius R1 from a cylinder axis A. The inner wall 23 comprises passage openings 25 and acts as a manifold for a liquid treated in the filter cartridge 21, such as water. The inner wall 23 is enveloped by a porous inner filter element 27 which, together with an outer filter element 29 arranged coaxially at a distance or radius R2 from the cylinder axis A, delimits a receiving space 30. This receiving space 30 can be filled with an active substance in accordance with the requirements of the respective application of the filter cartridge 21. The active substance may comprise, for example, activated carbon, malic acid, or a bioactive polymer. At least the outer filter element 29 comprises one or more plies of a nonwoven fabric coated according to the invention with at least two different metals. The average pore size or average diameter of through-openings between fibers of the nonwoven fabric may, for example, be of the order of magnitude of 0.8 to 80 micrometers and in particular approximately 1 to approximately 5 micrometers. The same preferably also applies to the inner filter element 27. For ultrafiltration applications, pore sizes can also be substantially smaller and for example be in the range from approximately 10 nm to approximately 30 nm. Due to their high toughness and stability, polysulfones are particularly well suited to such applications.

The number of plies of nonwoven fabric wound on the outer filter element 29 is for example between 2 and 50 and preferably between approximately 4 and approximately 20. This number is generally greater than or equal to that for the inner filter element 27. As a result, any heavy metal particles present can be efficiently bound from the water to be filtered before they can penetrate further into the interior of the filter cartridge 21. The thickness of a ply of the nonwoven fabric may, for example, be of the order of magnitude of approximately 0.2 mm to approximately 1 mm and in particular in the range from approximately 0.5 mm to 0.75 mm. The specific area density for such nonwoven fabrics is of the order of magnitude of approximately 40 g/m² to approximately 400 g/m² and amounts for example to approximately 50 g/m² or 170 g/m². Examples of suitable nonwoven fabrics are microfilament nonwoven fabrics.

Optionally, the outer filter element 29 may, similarly to the manifold, comprise an outer wall with inlet openings for the liquid (not shown), with one or more plies of the coated nonwoven fabric being wound onto this outer wall. This outer wall increases the stability of the outer filter element 29 and thus also of the filter cartridge 21.

The outer filter element 29 may optionally be enveloped by a protective envelope with inlet openings for the liquid to be treated (not shown). The two end faces of the filter cartridge 21 are each closed by a cover 31, at least one of these covers 31 comprising a central outlet orifice 33. Water penetrates under pressure radially from the outside through the outer filter element 29 into the receiving space 30. The great majority, preferably more than 99%, of microorganisms are rendered harmless by the coated sheet structure 3 or by free radicals on its surface. Heavy metal particles are additionally captured and retained by free radicals on the outer filter element 29. In the receiving space 30, the water is exposed to the active substance and then flows through the inner filter element 27 into the manifold. The inner filter element 27 here constitutes a further purification stage with a microbicidal effect. The purified water can be discharged via the outlet orifices 33.

FIG. 4 shows another exemplary embodiment of an article with an antibacterial finish in the form of a respirator mask. The latter comprises a filter element 41 with one or more layers of a porous sheet structure 3, in particular of a nonwoven fabric, coated according to the invention with a plurality of metals such as titanium, silver and copper. The sheet structure 3 or a plurality of plies of the sheet structure 3 may, as for example shown in FIG. 3, be embedded between two outer plies of the filter element 41, these outer plies having a shape adapted or adaptable to the anatomy of the human head. Such respirator masks generally comprise additional stiffeners 43 which enable adaptation to the contour of individual faces, for example in the region of the nasal bone, as well as elastic loops 45 for fastening to the ears.

FIG. 5 shows a garment, namely a T-shirt 51, as another exemplary embodiment of an article with an antibacterial finish. In the underarm areas, the T-shirt comprises inserts 53 of a sheet structure 3 coated according to the invention. The inserts may for example take the form of woven fabric or mesh structures coated on one or both sides or may alternatively be embedded in a protected manner between mesh-like layers of the garment.

1. An article with an antibacterial finish, the article comprising:
at least one electrically nonconductive substrate with at least one surface portion coated with particles of titanium and one or more further metals,
the particles are arranged in various combinations in clusters and are electrically conductively connected together within such clusters, and
the clusters are arranged on the substrate at a distance from each other as islands and electrically insulated from each other.

2. The article with an antibacterial finish according to claim 1, wherein an characterized in that the average cluster size is smaller than 100 nm.

3. The article with an antibacterial finish according to claim 1, wherein the further metal or metals is/are selected from a group comprising silver, copper, gold, iron and nickel.

4. The article with an antibacterial finish according to claim 3, wherein the one of the further metals is silver, and a coated mass of silver particles per m² of surface in a coated surface region of the substrate is in a range from 50 mg to 100 mg.

5. The article with an antibacterial finish according to claim 1, wherein the substrate is coated with titanium, and the further metals of silver and copper, and a ratio of a number of particles of copper:silver is in a range from 1:2 to 1:6.

6. The article with an antibacterial finish according to claim 1, wherein the substrate is coated with titanium, and the further metals of copper and gold, and a ratio of a number of particles of copper:silver is in a range from 1:2 to 1:4, and a ratio of a number of particles of copper:gold is in a range from 2:1 to 8:1.

7. The article with an antibacterial finish according to claim 1, wherein the substrate is a textile sheet structure (3) with a porous fiber structure.

8. The article with an antibacterial finish according to claim 1, wherein the article is a filter cartridge, an air filter, a protective mask, a wound dressing, a garment, an insole, a cleaning cloth or an antiseptic pad, and at least one ply of the substrate is at least one of arranged on a surface of the article or embedded in the article.

9. The article with an antibacterial finish according to claim 8, wherein the article is filter cartridge (21), the filter cartridge (21) comprises a cylindrical inner filter element (27) and, coaxially thereto, a cylindrical outer filter element (29) which together delimit a receiving space (30) for an active substance, and each of the filter elements (27, 29) comprises one or more plies of the coated substrate.

10. A method for producing an article with an antibacterial finish, the article comprising at least one electrically nonconductive substrate, the method comprising:
coating at least one portion of a surface of substrate in a sputtering installation by sequential sputtering of particles of titanium and one or more further metals,
depositing the sputtered particles in various combinations in clusters on the respective surface portion of the substrate and, within these clusters, being electrically conductively connected together, and
arranging the clusters on the substrate at a distance from each other as islands that are electrically insulated from each other.

11. The article with an antibacterial finish according to claim 1, wherein the substrate is a non-textile sheet structure (3) with a porous fiber structure.
